(19) United States
(12) Patent Application Publication
(10) Pub. No.: US 2024/0271317 A1
(43) Pub. Date: Aug. 15, 2024

(54) Crystal Puller and Method for Pulling Single-Crystal Silicon Ingot, and Single-Crystal Silicon Ingot

(71) Applicant: XI’AN ESWIN MATERIAL TECHNOLOGY CO., LTD., Xi'an (CN)

(72) Inventors: Zhenliang SONG, Xi'an (CN); Shaojie SONG, Xi'an (CN)

(21) Appl. No.: 18/568,227

(22) PCT Filed: Sep. 30, 2022
(86) PCT No.: PCT/CN2022/122976

§ 371 Date: Dec. 7, 2023

(30) Foreign Application Priority Data
Jan. 5, 2022 (CN) 202210007056.4

(51) Int. Cl. C30B 15/20; C30B 15/10; C30B 29/06

(52) U.S. Cl. CPC C30B 15/203; C30B 15/10; C30B 29/06

(57) ABSTRACT

A crystal puller for pulling a single-crystal silicon ingot includes a cylindrical heating apparatus and a cylindrical cooling apparatus. The heating apparatus is located above a water cooling jacket, and is configured such that a single-crystal silicon ingot enters a heat treatment chamber defined by the heating apparatus to be heat-treated when the single-crystal silicon ingot moves upwardly in a vertical direction. The cooling apparatus is located above the heating apparatus, and is configured such that the heat-treated single-crystal silicon ingot enters a cooling chamber defined by the cooling apparatus to be cool-treated when the single-crystal silicon ingot continues moving upwardly in the vertical direction.

### CROSS-REFERENCE TO RELATED APPLICATION

The present application is a U.S. national phase application of a PCT Application No. PCT/CN2022/122976 filed on Sep. 30, 2022, which claims a priority of the Chinese patent application No. 202210007056.4 filed in China on Jan. 5, 2022, disclosures of which are incorporated herein by reference in their entireties.

### TECHNICAL FIELD

Embodiments of the present disclosure relate to the field of semiconductor manufacturing technologies, in particular to a crystal puller for pulling single-crystal silicon ingot, a method for pulling single-crystal silicon ingot, and a single-crystal silicon ingot.

### BACKGROUND

In recent years, with the development of miniaturization in the manufacturing of semiconductor devices, the requirements for the required silicon wafers become increasingly higher. It is not only required that the surface regions of the silicon wafers have few or no defects, but also that the silicon wafers have sufficient bulk micro defects (BMDs) to protect the silicon wafer regions where electronic components are provided from contaminations of heavy metal impurities. The heavy metal impurities contained in silicon wafers have become an important factor affecting the quality of semiconductor devices. Therefore, the content of heavy metal impurities needs to be minimized during the production process of silicon wafers. It is known that when sufficient BMDs are formed inside the silicon wafer, the BMDs have an intrinsic gettering (IG) effect of capturing heavy metal impurities, which can greatly improve the poor quality problem of semiconductor devices caused by heavy metal impurities. In recent years, the demand for silicon wafers with BMD density equal to or greater than 1×10⁸ BMDs/cm³ has increased. Therefore, when supplying silicon wafers to electronic component manufacturers, it is necessary to have sufficient BMD nuclei in the substrate silicon wafers to obtain high BMD density.

### SUMMARY

Technical solutions of embodiments of the present disclosure are implemented as follows.

In a first aspect, an embodiment of the present disclosure provides a crystal puller for pulling a single-crystal silicon ingot, comprising: a cylindrical heating apparatus located above a water cooling jacket, wherein the heating apparatus is configured such that a single-crystal silicon ingot enters a heat treatment chamber defined by the heating apparatus to be heat-treated when the single-crystal silicon ingot moves upwardly in a vertical direction; and a cylindrical cooling apparatus located above the heating apparatus, wherein the cooling apparatus is configured such that the heat-treated single-crystal silicon ingot enters a cooling chamber defined by the cooling apparatus to be cool-treated when the single-crystal silicon ingot continues moving upwardly in the vertical direction.

In a second aspect, an embodiment of the present disclosure provides a method for pulling a single-crystal silicon ingot, comprising: placing and melting a polycrystalline silicon raw material in a quartz crucible and lowering a seed crystal to pull the single-crystal silicon ingot; pulling the single-crystal silicon ingot upwardly in a vertical direction at a predetermined pulling speed V into the heat treatment chamber defined by the heating apparatus to be heat-treated; continuing pulling the heat-treated single-crystal silicon ingot upwardly in the vertical direction at the predetermined pulling speed V into the cooling chamber defined by the cooling apparatus to be cool-treated.

In a third aspect, an embodiment of the present disclosure provides a single-crystal silicon ingot, wherein the single-crystal silicon ingot is pulled using the method according to the second aspect.

### BRIEF DESCRIPTION OF THE DRAWINGS

FIG. 1 is a schematic structural view of a crystal puller in the related art;

FIG. 2 is a schematic structural view of a crystal puller for pulling a single-crystal silicon ingot according to an embodiment of the present disclosure;

FIG. 3 is a schematic view showing a relationship between internal defect distribution of a single-crystal silicon ingot and V/G distribution according to an embodiment of the present disclosure;

FIG. 4 is a flow diagram of a method for pulling a single-crystal silicon ingot according to an embodiment of the present disclosure;

FIG. 5 is a schematic view showing a temperature field, obtained through numerical simulation, of a single-crystal silicon ingot pulled by a crystal puller according to an embodiment of the present disclosure;

FIG. 6 is a schematic view showing a temperature field, obtained through numerical simulation, of a single-crystal silicon ingot pulled by a crystal puller in the related art.

### DETAILED DESCRIPTION

The technical solutions in the embodiments of the present disclosure will be described hereinafter in conjunction with the drawings of the embodiments of the present disclosure in a clear and thorough manner.

An epitaxial silicon wafer is produced by growing a single-crystal layer (also called an epitaxial layer) on a silicon wafer through a vapor deposition reaction. Because the epitaxial layer has high crystalline integrity and almost no defects, epitaxial silicon wafers are widely used as a substrate material for semiconductor devices. However, during the epitaxial growth process, because the silicon wafer is exposed to an environment with a high temperature of above 1000° C., smaller BMD nuclei will be eliminated. Therefore, a sufficient quantity of BMD nuclei cannot be provided in the epitaxial silicon wafers, which leads to an insufficient BMD density of semiconductor devices manufactured from the epitaxial silicon wafers, resulting in poor quality of the manufactured semiconductor devices.

In order to solve the problem of reduced BMD density in the epitaxial silicon wafers, nitrogen doping is usually performed during the pulling process of single-crystal silicon ingots to obtain stable BMD nuclei; however, for nitrogen-doped silicon wafers, the existence of peripheral oxidation induced stacking faults (OSF) regions will cause the BMD density to decrease and cause defective etch pits (EPs) to occur.

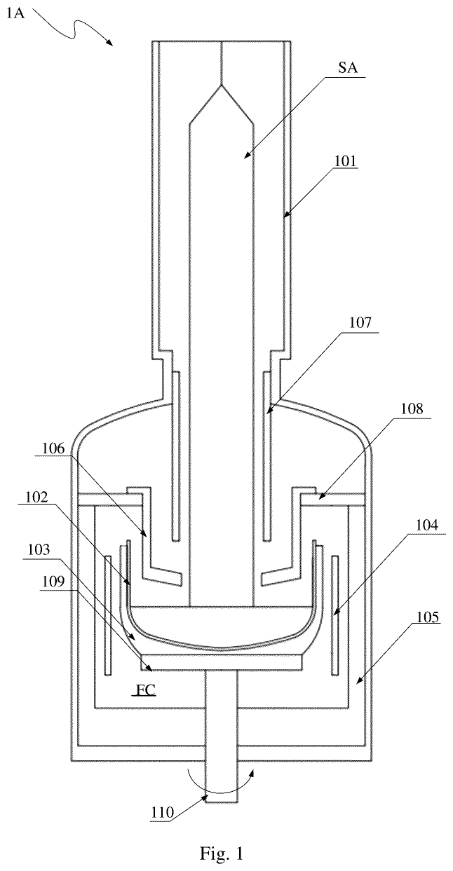

Refer to FIG. 1, which shows a crystal puller 1A in the related art. As shown in FIG. 1, the crystal puller 1A may comprise:
a puller body 101, the puller body 101 defining a puller cavity (FC);
a quartz crucible 102, the quartz crucible 102 being located at the bottom of the puller cavity (FC) defined by the puller body 101, and being used for accommodating a solid polycrystalline silicon raw material in the initial stage of preparing single-crystal silicon ingot SA;
a graphite crucible 103, the graphite crucible 103 being located on the periphery of the quartz crucible 102, for supporting and immobilizing the quartz crucible 102;
a crucible heater 104, the crucible heater 104 being located on the periphery of the graphite crucible 103 to heat the quartz crucible 102 and the graphite crucible 103, thereby melting the polycrystalline silicon raw material contained in the quartz crucible 102 into a silicon melt;
a puller side wall thermal insulation element 105, the puller side wall thermal insulation element 105 being located at the inner side of the cylindrical puller side wall of the puller body 101 to prevent the heat generated by the crucible heater 104 from being lost through the puller side wall;
an inverted conical-cylindrical reflector 106, the reflector 106 being located above the quartz crucible 102 for guiding an inert gas such as argon downward to the space above the silicon melt in the quartz crucible 102, wherein the radial size of an upper portion of the reflector 106 is less than the radial size of the puller body 101, and is fastened to the side wall of the puller body 101 by means of a horizontal reflector holder (not shown in the figure);
a cylindrical water cooling jacket 107, the radial size of the water cooling jacket 107 being less than the radial size of the upper portion of the reflector 106, so that the water cooling jacket 107 may be located over the reflector 106 in a manner of overlapping the reflector 106 in a vertical direction, for cooling the pulled single-crystal silicon ingot SA;
an annular plate-shaped thermal insulation cover 108, the thermal insulation cover 108 being a single-layer cover plate made of a material such as graphite, and the thermal insulation cover 108 being horizontally located above the flow guide cylinder holder of the puller side wall thermal insulation element 105, with the outer rim of the thermal insulation cover 108 being in contact with the side wall of the puller body 101 and the inner rim of the thermal insulation cover 108 being in contact with the reflector 106, in order to prevent the heat generated by the crucible heater 104 from being lost through the top of the puller body 101;
a crucible tray 109, the crucible tray 109 being, e.g., a graphite support for supporting the graphite crucible 103;
a crucible rotating mechanism 110, the crucible rotating mechanism 110 being used for driving the quartz crucible 102 and the graphite crucible 103 to rotate.

When the crystal puller 1A is used for pulling a single-crystal silicon ingot SA, first, a high-purity polycrystalline silicon raw material is placed in the quartz crucible 102, and the quartz crucible 102 is continuously heated by the crucible heater 104 while the quartz crucible 102 is being driven to rotate by the crucible rotation mechanism 110, to melt the polycrystalline silicon raw material contained in the quartz crucible 102, i.e., melt the polycrystalline silicon raw material into a silicon melt, wherein the heating temperature is maintained at about one thousand degrees Celsius, and the gas in the puller is usually an inert gas, thereby the polycrystalline silicon raw material is melted without generating unnecessary chemical reactions. When the liquid surface temperature of the silicon melt is controlled at the critical point of crystallization by controlling the thermal field provided by the crucible heater 104, the seed crystal (not shown in the figure) located above the liquid surface is pulled vertically upward from the liquid surface. As the seed crystal is pulled upwardly, the silicon melt grows into a single-crystal silicon ingot SA with the same crystal orientation as the seed crystal. In order to produce the finally produced silicon wafers with a high BMD density, nitrogen doping can be performed during the pulling process of the single-crystal silicon ingot SA. For example, nitrogen can be injected into the puller chamber of single-crystal puller 1A during the pulling process, or silicon wafers containing nitrogen can be added into the silicon melt in the quartz crucible 102. In this way, the pulled single-crystal silicon ingot SA and the silicon wafers sliced from the single-crystal silicon ingot SA will be nitrogen-doped.

However, during the process of generating epitaxial silicon wafers, through epitaxial deposition reaction, based on the silicon wafers prepared according to the above method, smaller BMD nuclei in the silicon wafers will be eliminated due to the epitaxial deposition reaction temperature of 1000° C., so a sufficient quantity of BMD nuclei cannot be provided in the epitaxial silicon wafers. In order to avoid the above problem, in the related art, a single-crystal silicon ingot SA with a larger diameter is pulled, and the OSF portion at the periphery of the single-crystal silicon ingot SA is removed through grinding. However, this operation causes loss of single-crystal silicon ingot SA and excessive time cost.

In addition, in the related art, heat treatment is also performed on the aforementioned silicon wafers to obtain more BMD nuclei. However, during the heat treatment process, the silicon wafers are usually susceptible to metal contamination, and the heat treatment is time-consuming and incurs high cost.

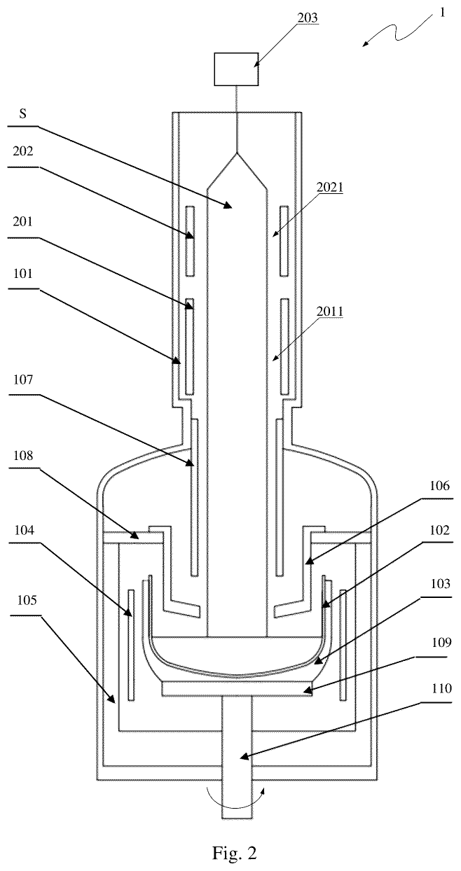

In view of the above, in order to improve the BMD density of the single-crystal silicon ingot SA and silicon wafers prepared therefrom, a crystal puller 1 as shown in FIG. 2 is provided in an embodiment of the present disclosure. As shown in FIG. 2, the crystal puller 1 specifically comprises:
a cylindrical heating apparatus 201 located above a water cooling jacket 107, wherein the heating apparatus 201 is configured such that a single-crystal silicon ingot S enters a heat treatment chamber 2011 defined by the heating apparatus 201 to be heat-treated when the single-crystal silicon ingot S moves upwardly in a vertical direction;
a cylindrical cooling apparatus 202 located above the heating apparatus 201, wherein the cooling apparatus 202 is configured such that the heat-treated single-crystal silicon ingot S enters a cooling chamber 2021 defined by the cooling apparatus 202 to be cool-treated when the single-crystal silicon ingot S continues moving upwardly in the vertical direction.

In the crystal puller 1 shown in FIG. 2, a cylindrical heating apparatus 201 is located above the water cooling jacket 107, and the heating apparatus 201 is configured to allow the single-crystal silicon ingot S to enter the heat treatment chamber 2011 defined by the heating apparatus 201 and to be heat-treated when the single-crystal silicon ingot S moves upwardly in the vertical direction; and a cylindrical cooling apparatus 202 is located above the heating apparatus 201, and the cooling apparatus 202 is configured to allow the heat-treated single-crystal silicon ingot S to enter the cooling chamber 2021 defined by the cooling apparatus 202 to be cool-treated when the single-crystal silicon ingot S continues moving upwardly in the vertical direction; with the crystal puller 1, the temperature field of the single-crystal silicon ingot S can be changed, such that the single-crystal silicon ingot S is at a temperature suitable for BMD nucleation and growth, and with the cooling apparatus 202, the cooling speed of the single-crystal silicon ingot S can be controlled to facilitate the BMD nucleation, thereby increasing the BMD density of the single-crystal silicon ingot S.

It can be understood that with the technical solution shown in FIG. 2, the BMD density in the epitaxial silicon wafer is able to meet the requirements in customer specifications, without performing nitrogen doping on the single-crystal silicon ingot S or performing heat treatment on the silicon wafers made from the single-crystal silicon ingot S.

For the technical solution shown in FIG. 2, in some possible implementations, as shown in FIG. 2, the crystal puller 1 further comprises a pulling mechanism 203, and the pulling mechanism 203 is configured to cause a ratio V/G between a pulling speed V (mm/min) of the single-crystal silicon ingot S upwardly in the vertical direction and an average temperature gradient G (° C./mm) of the single-crystal silicon ingot S in an axial direction of the single-crystal silicon ingot S to be between 1.1 times (V/G)_{critical} and 1.2 times (V/G)_{critical}; wherein the (V/G)_{critical} refers to the V/G value which is defined to contribute to a crystal region at the boundary between a Pv region and a Pi region.

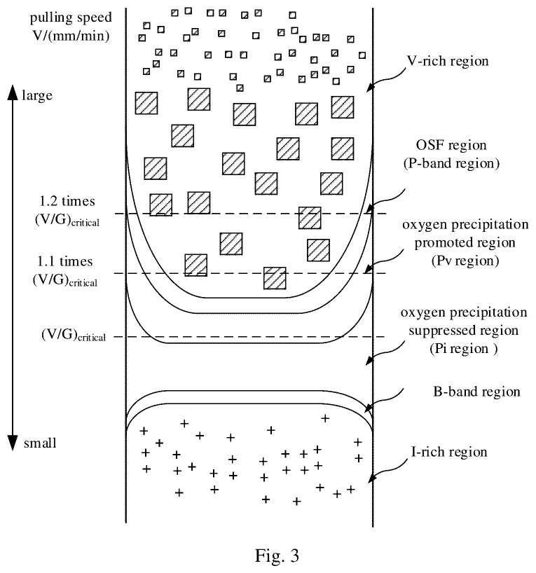

It should be noted that, as shown in FIG. 3, the region in the single-crystal silicon ingot S that has a BMD density equal to or greater than 1×10⁸ BMDs/cm³ is defined as containing an oxygen precipitation promoted region (hereinafter referred to as “Pv region”), an OSF region, and a vacancy-rich region (hereinafter referred to as “V-rich region”), wherein the OSF region is also known as the P-band region (hereinafter referred to as P-band region); and the region in the single-crystal silicon ingot S that has a BMD density less than 1×10⁸ BMDs/cm³ is defined as containing an oxygen precipitation suppressed region (hereinafter referred to as “Pi region”), a B-band region (hereinafter referred to as B-band region), and an interstitial silicon-rich region (hereinafter referred to as “I-rich region”); the V/G ratio value at the boundary between the Pv region and the Pi region is defined as the (V/G)_{critical}.

It can be understood that during the pulling process of single-crystal silicon ingot S, when a higher pulling speed is used for pulling single-crystal silicon ingot S, optionally, when the V/G is between 1.1 times the (V/G)_{critical} and 1.2 times the (V/G)_{critical}, this higher pulling speed allows the single-crystal silicon ingot S to crystallize and grow into the V-rich region, so that the cross-section of single-crystal silicon ingot S is dominated by vacancy defects, which is mainly because BMDs are formed by the deposition of impurity oxygen in the vacancy defects. In actual production, BMDs will be formed in the vacancy defect region and vacancy-rich region of the single-crystal silicon ingot S. Besides, if single-crystal silicon ingot S contains the vacancy defect region, it will affect the integrity of the gate oxide film in the silicon wafer prepared from the single-crystal silicon ingot S. Since impurity oxygen cannot deposit in the I-rich region, BMDs cannot be formed in the I-rich region. Therefore, only the V-rich region in the single-crystal silicon ingot can generate high density of BMDs, thereby obtaining a silicon wafer with a highly clean surface.

Optionally, for the technical solution shown in FIG. 2, the heating apparatus 201 is used for providing a heat treatment temperature of 600° C. to 800° C. It can be understood that the heating apparatus 201 is used for heating the single-crystal silicon ingot S to maintain the heat treatment temperature of the single-crystal silicon ingot S at between 600° C. and 800° C., since the heat treatment temperature between 600° C. and 800° C. is conducive to BMD nucleation and growth, and can prevent the elimination of smaller BMD nuclei caused by high temperature environments above 1000° C. during the epitaxial growth process, which is helpful in ensuring that the BMD density in the finally obtained epitaxial silicon wafer meets requirements in customer specifications.

Optionally, for the technical solution shown in FIG. 2, the cooling apparatus 202 is configured such that the cooling speed of the heat-treated single-crystal silicon ingot is greater than 2.7° C./min, to increase the density of BMD nuclei. In the embodiments of the present disclosure, a cooling apparatus 202 is located above the heating apparatus 201 to control the cooling temperature and the cooling speed of the heat-treated single-crystal silicon ingot S, since the density of saturated BMDs is related to the cooling speed of single-crystal silicon ingot S, and a higher cooling speed can increase the density of BMD nuclei; rapid cooling of the heat-treated single-crystal silicon ingot S can suppress the recombination of internal vacancies in the single-crystal silicon ingot S, ensuring a high concentration of vacancies remain in the finally obtained single-crystal silicon ingot S, and thus ensuring the acquisition of sufficient BMD nuclei. It should be noted that in the embodiments of the present disclosure, in order to provide different BMD densities required by different customer specifications, the cooling apparatus 202 can be controlled to provide different cooling speeds of single-crystal silicon ingot S, thereby controlling the density of the BMD nuclei in the single-crystal silicon ingot S.

For the technical solution shown in FIG. 2, the crystal puller 1 further comprises the water cooling jacket 107, and the water cooling jacket 107 is configured to rapidly cool the pulled single-crystal silicon ingot S from 1150° C. to 1020° C., so that the cooling speed of the single-crystal silicon ingot S is greater than 2.7° C./min, to suppress the recombination of vacancy defects in the single-crystal silicon ingot S, thereby ensuring that the single-crystal silicon ingot S is dominated by vacancy defects.

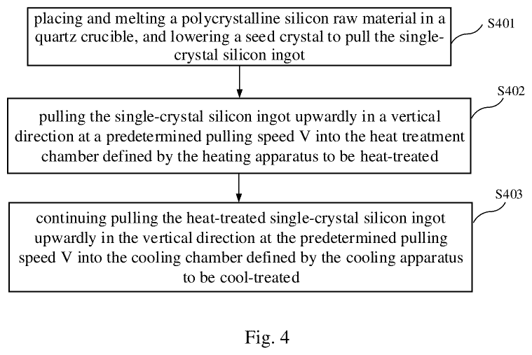

FIG. 4 shows a method for pulling a single-crystal silicon ingot according to an embodiment of the present disclosure, the method comprises:
S401: placing and melting a polycrystalline silicon raw material in a quartz crucible 102, and lowering a seed crystal to pull the single-crystal silicon ingot S;
S402: pulling the single-crystal silicon ingot S upwardly in a vertical direction at a predetermined pulling speed V into the heat treatment chamber 2011 defined by the heating apparatus 201 to be heat-treated;
S403: continuing pulling the heat-treated single-crystal silicon ingot S upwardly in the vertical direction at the predetermined pulling speed V into the cooling chamber 2021 defined by the cooling apparatus 202 to be cool-treated.

For the technical solution shown in FIG. 4, in the crystal puller 1, the single-crystal silicon ingot S is firstly subjected to heat treatment, then subjected to cooling treatment. The temperature field of the single-crystal silicon ingot S is controlled by controlling the V/G parameter, heat treatment temperature and duration, as well as cooling temperature and duration following the heat treatment process of the single-crystal silicon ingot S, in order to control the nucleation and growth of BMD nuclei inside the single-crystal silicon ingot S, and thereby improve the density of BMDs in the single-crystal silicon ingot.

Optionally, for the technical solution shown in FIG. 4, the ratio parameter V/G between the pulling speed V (mm/min) of the single-crystal silicon ingot S vertically upward and the average temperature gradient G (° C./mm) of the single-crystal silicon ingot in an axial direction of the single-crystal silicon ingot S is between 1.1 times (V/G)_{critical} and 1.2 times (V/G)_{critical}; wherein the (V/G)_{critical} refers to the V/G value which is defined to contribute to a crystal region at the boundary between the Pv region and the Pi region.

Optionally, for the technical solution shown in FIG. 4, the heating apparatus 201 is used for providing a heat treatment temperature of 600° C. to 800° C.

Optionally, for the technical solution shown in FIG. 4, the cooling apparatus 202 is configured such that the cooling speed of the heat-treated single-crystal silicon ingot S is greater than 2.7° C./min.

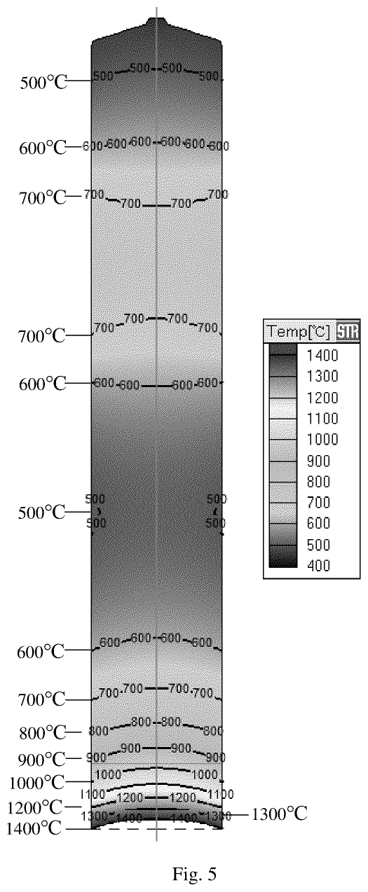

For example, refer to FIG. 5, which is a schematic view showing a temperature field, obtained through numerical simulation, of a single-crystal silicon ingot S pulled using the crystal puller 1, where the V/G of the pulled single-crystal silicon ingot S is between 1.1 times the (V/G)_{critical} and 1.2 times the (V/G)_{critical}. As can be seen from FIG. 5, in the crystal puller 1, the temperature range of 600° C. to 800° C. accounts for a large portion of the temperature field of the single-crystal silicon ingot S pulled utilizing the parameter V/G, which means that the large portion of temperature field is all beneficial to BMD nucleation and growth. It should be noted that in the crystal puller 1, when the parameter V/G is used for pulling the single-crystal silicon ingot S, the single-crystal silicon ingot S stays in the temperature range of 600° C. to 800° C. for approximately 570 minutes.

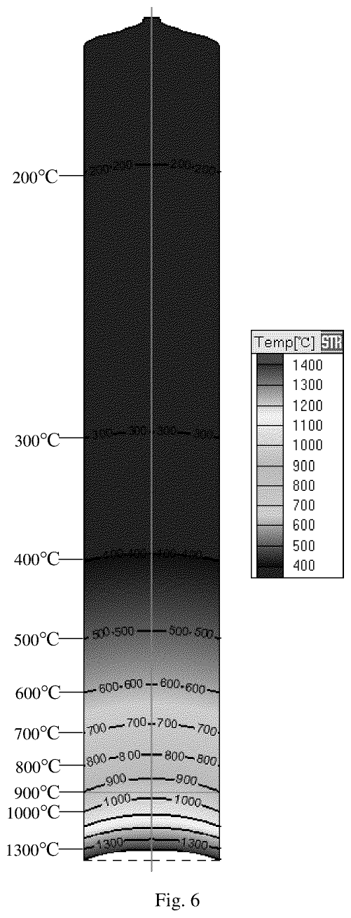

Similarly, using the same numerical simulation conditions, the temperature field of the single-crystal silicon ingot SA pulled using the puller 1A was numerically simulated. The obtained temperature field is shown in FIG. 6. As can be seen from FIG. 6, in the crystal puller 1A, the temperature range of 600° C. to 800° C. accounts for a small portion of the temperature field of the single-crystal silicon ingot SA pulled utilizing the parameter V/G, which means that only the small portion of temperature field is suitable for BMD nucleation and growth. It should be noted that in the crystal puller 1A, when the parameter V/G is used for pulling the single-crystal silicon ingot SA, the single-crystal silicon ingot SA stays in the temperature range of 600° C. to 800° C. for approximately 158 minutes.

Finally, embodiments of this disclosure also provide a single-crystal silicon ingot, which is obtained by pulling according to the method described in the aforementioned technical solutions.

It should be noted that the technical solutions set forth in the embodiments of this disclosure can be combined arbitrarily when there is no conflict.

The aforementioned are merely specific implementations of the present disclosure, but the scope of the disclosure is by no means limited thereto. Any modifications or replacements that would easily occur to those skilled in the art, without departing from the technical scope disclosed in the disclosure, should be encompassed in the scope of the present disclosure. Therefore, the scope of the present disclosure is to be determined by the scope of the claims.

1. A crystal puller for pulling a single-crystal silicon ingot, comprising:
a cylindrical heating apparatus located above a water cooling jacket, wherein the heating apparatus is configured such that a single-crystal silicon ingot enters a heat treatment chamber defined by the heating apparatus to be heat-treated when the single-crystal silicon ingot moves upwardly in a vertical direction;
a cylindrical cooling apparatus located above the heating apparatus, wherein the cooling apparatus is configured such that the heat-treated single-crystal silicon ingot enters a cooling chamber defined by the cooling apparatus to be cool-treated when the single-crystal silicon ingot continues moving upwardly in the vertical direction.

2. The crystal puller according to claim 1, wherein the crystal puller further comprises a pulling mechanism, and the pulling mechanism is configured such that a ratio parameter V/G between a pulling speed V of the single-crystal silicon ingot upwardly in the vertical direction and an average temperature gradient G of the single-crystal silicon ingot in an axial direction of the single-crystal silicon ingot is between 1.1 times (V/G)_{critical} and 1.2 times (V/G)_{critical}, wherein the (V/G)_{critical} refers to a V/G value which is defined to contribute to a crystal region at a boundary between an oxygen precipitation promoted region and an oxygen precipitation suppression region.

3. The crystal puller according to claim 1, wherein the heating apparatus is used for providing a heat treatment temperature of 600° C. to 800° C.

4. The crystal puller according to claim 1, wherein the cooling apparatus is configured such that a cooling speed of the heat-treated single-crystal silicon ingot is greater than 2.7° C./min.

5. The crystal puller according to claim 1, wherein the crystal puller further comprises the water cooling jacket, and the water cooling jacket is configured such that the single-crystal silicon ingot obtained by pulling is cooled from 1150° C. to 1020° C. at a cooling speed greater than 2.7° C./min.

6. A method for pulling a single-crystal silicon ingot, comprising:
placing and melting a polycrystalline silicon raw material in a quartz crucible, and lowering a seed crystal to pull the single-crystal silicon ingot;
pulling the single-crystal silicon ingot upwardly in a vertical direction at a predetermined pulling speed V into a heat treatment chamber defined by a heating apparatus to be heat-treated;
continuing pulling the heat-treated single-crystal silicon ingot upwardly in the vertical direction at the predetermined pulling speed V into a cooling chamber defined by a cooling apparatus to be cool-treated.

7. The method according to claim 6, wherein a ratio parameter V/G between the pulling speed V of the single-crystal silicon ingot upwardly in the vertical direction and an average temperature gradient G of the single-crystal silicon ingot in an axial direction of the single-crystal silicon ingot is between 1.1 times (V/G)_{critical} and 1.2 times (V/G)_{critical}, wherein the (V/G)_{critical} refers to a V/G value which is defined to contribute to a crystal region at a boundary between an oxygen precipitation promoted region and an oxygen precipitation suppression region.

8. The method according to claim 6, wherein the heating apparatus is used for providing a heat treatment temperature of 600° C. to 800° C.

9. The method according to claim 6, wherein the cooling apparatus is configured such that a cooling speed of the heat-treated single-crystal silicon ingot is greater than 2.7° C./min.

10. A single-crystal silicon ingot, wherein the single-crystal silicon ingot is pulled by a single-crystal silicon ingot pulling method, comprising:
placing and melting a polycrystalline silicon raw material in a quartz crucible, and lowering a seed crystal to pull the single-crystal silicon ingot;
pulling the single-crystal silicon ingot upwardly in a vertical direction at a predetermined pulling speed V into a heat treatment chamber defined by a heating apparatus to be heat-treated;
continuing pulling the heat-treated single-crystal silicon ingot upwardly in the vertical direction at the predetermined pulling speed V into a cooling chamber defined by a cooling apparatus to be cool-treated.

11. The single-crystal silicon ingot according to claim 10, wherein a ratio parameter V/G between the pulling speed V of the single-crystal silicon ingot upwardly in the vertical direction and an average temperature gradient G of the single-crystal silicon ingot in an axial direction of the single-crystal silicon ingot is between 1.1 times (V/G)_{critical} and 1.2 times (V/G)_{critical}, wherein the (V/G)_{critical} refers to a V/G value which is defined to contribute to a crystal region at a boundary between an oxygen precipitation promoted region and an oxygen precipitation suppression region.

12. The single-crystal silicon ingot according to claim 10, wherein the heating apparatus is used for providing a heat treatment temperature of 600° C. to 800° C.

13. The single-crystal silicon ingot according to claim 10, wherein the cooling apparatus is configured such that a cooling speed of the heat-treated single-crystal silicon ingot is greater than 2.7° C./min.
